(19) United States
(12) Patent Application Publication
(10) Pub. No.: US 2007/0235880 A1
(43) Pub. Date: Oct. 11, 2007

(54) SEMICONDUCTOR DEVICE AND METHOD OF FABRICATING THE SAME

(76) Inventor: Chin-Sheng Yang, Hsinchu (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/308,492

(22) Filed: Mar. 30, 2006

(51) Int. Cl. H01L 23/48

(52) U.S. Cl. 257/773

(57) ABSTRACT

A semiconductor device including a composite structure and a contact is provided. The composite structure includes a bottom electrode, an insulating layer, and an upper electrode from bottom to top. The contact electrically connects the upper electrode and the bottom electrode. The composite structure is used as a resistor, and its resistance is increased by electrically connecting the upper electrode and the bottom electrode through the contact, doubling the current path.

### BACKGROUND OF THE INVENTION

1. Field of the Invention

The present invention relates to an integrated circuit structure and a method of fabricating the same, and more particularly, to a resistor and semiconductor device and a fabrication method thereof.

2. Description of Related Art

Resistors are common devices in ordinary circuits, and are essential devices in memory and logic circuits. The resistance R generated by a resistor is a function of length and sectional area, i.e. R=ρL/A, where ρ is the material resistance, L is the length of the resistor in a current transmission direction, and A is the sectional area of the resistor in the current transmission direction.

A conventional resistor in an integrated circuit usually is a resistor of lightly doped polysilicon or a metal or metal compound with high resistance. Along with the progress of semiconductor device integrity, the requirements as to the properties of various materials for manufacturing semiconductor devices have been relatively enhanced, in order to form a device with the same or even better properties in a smaller area or space. When the resistance required in the device circuit design is high, a resistor layer with an extremely large area hinders the progress of semiconductor device integration, and also increases the inconvenience for the semiconductor process.

Besides, current electronic products often demand forming a resistor and a capacitor on the same chip. Therefore, how to integrate the processes of the resistor and the capacitor and form a resistor with higher resistance yet of the same size, or even reduce the resistor size, has become an urgent problem to be solved at present.

### SUMMARY OF THE INVENTION

In view of the above, an object of the present invention is to provide a semiconductor device. The semiconductor device can be used as a resistor, and the resistance thereof can be raised without increasing the device size.

Another object of the present invention is to provide a method for manufacturing the semiconductor device, in which the processes of a resistor and a capacitor are integrated, and a resistor with better performance can be fabricated.

The present invention provides a semiconductor device, which includes a composite structure and a contact. The composite structure comprises a bottom electrode, an insulating layer, and an upper electrode from bottom to top. The contact electrically connects the upper electrode and the bottom electrode.

According to an embodiment of the present invention, the contact is disposed on a sidewall of the composite structure.

According to an embodiment of the present invention, a first wire structure is disposed on the composite structure and electrically connected with the upper electrode. The contact is electrically connected with the upper electrode via the first wire structure. The size of the bottom electrode is larger than the size of the upper electrode, and the contact is disposed between the first wire structure and the bottom electrode.

According to an embodiment of the present invention, a second wire structure is disposed under the bottom electrode and electrically connected with the bottom electrode. The contact is electrically connected with the bottom electrode via the second wire structure.

According to an embodiment of the present invention, a first fuse structure is disposed in the first wire structure. When the first fuse structure passes the current, the composite structure is used as a resistor. When the first fuse structure stops passing the current, the composite structure is used as a capacitor.

According to an embodiment of the present invention, a second fuse structure is disposed in the second wire structure.

According to an embodiment of the present invention, the material of the upper and bottom electrodes is selected from a group consisting of Ti, TiN, TiNSi, Ta, TaN, TaC, TaNSi, TaAlN, W, WN, Cr—Ni alloy, CrSi₂, and any mixture thereof.

According to an embodiment of the present invention, the material of the insulating layer is selected from a group consisting of Ta₂O₅, SrTiO₃, ZrO₂, HfO₂, HfSiO, TiO₂, SiO₂, Si₃N₄, and any mixture thereof.

According to an embodiment of the present invention, the contact comprises Cu, Al, W, or an alloy thereof.

According to an embodiment of the present invention, the upper and bottom electrodes of the composite structure are electrically connected by the contact (and the wire structure), such that the composite structure is used as a resistor. As the current will pass through the upper and bottom electrodes, the current transmission path is doubled, thereby raising the resistance of the resistor. Therefore, even if the size of the resistor is halved, it can still satisfy the requirement for resistance, and is more beneficial to the miniaturization of device.

The present invention provides a method for manufacturing the semiconductor device. In the method, for example, a substrate is first provided. The substrate is at least formed with a conductive part therein. Then, a first dielectric layer is formed on the substrate. An interconnect structure is formed in the first dielectric layer, to electrically connect the conductive part. A composite structure is formed on the first dielectric layer. The composite structure is formed by stacking a bottom electrode, an insulating layer, and an upper electrode, in which the bottom electrode is electrically connected with the interconnect structure. A second dielectric layer is formed on the first dielectric layer, covering the composite structure. A conductor layer and a contact are formed in the second dielectric layer, in which the conductor layer is electrically connected with the upper electrode, and the contact electrically connects the upper electrode and the bottom electrode.

According to an embodiment of the present invention, the contact is formed on a sidewall of the composite structure.

According to an embodiment of the present invention, in the step of forming the conductor layer and the contact in the second dielectric layer, for example, an opening and a contact opening are first formed in the second dielectric layer. The opening exposes a part of the upper electrode, and the contact opening at least exposes the sidewalls of the upper electrode and the bottom electrode. Then, a conductive material is filled in the opening and the contact opening, to form the conductor layer and the contact.

According to an embodiment of the present invention, a step of forming a first wire structure in the second dielectric layer may be included in the step of forming the conductor layer and the contact. The first wire structure is electrically connected with the upper electrode, and the contact is electrically connected with the upper electrode by the first wire structure.

According to an embodiment of the present invention, the size of the bottom electrode is larger than that of the upper electrode, and the contact is formed between the first wire structure and the bottom electrode.

According to an embodiment of the present invention, it further comprises forming a fuse structure in the first wire structure.

According to an embodiment of the present invention, a step of forming a second wire structure in the first dielectric layer is included in the step of forming the interconnect structure. The bottom electrode is electrically connected with the second wire structure, and the contact extends to the first dielectric layer to connect the second wire structure, and is electrically connected with the bottom electrode via the second wire structure.

According to an embodiment of the present invention, the conductor layer can be an interconnect structure.

According to an embodiment of the present invention, the material of the upper electrode and the bottom electrode is selected from a group consisting of Ti, TiN, TiNSi, Ta, TaN, TaC, TaNSi, TaAlN, W, WN, Cr—Ni alloy, CrSi₂, and any mixture thereof.

According to an embodiment of the present invention, the material of the insulating layer is selected from a group consisting of Ta₂O₅, SrTiO₃, ZrO₂, HfO₂, HfSiO, TiO₂, SiO₂, Si₃N₄, and any mixture thereof.

According to an embodiment of the present invention, the contact comprises Cu, Al, W, or an alloy thereof.

According to an embodiment of the present invention, the step of forming the composite structure may further comprise a step of forming a MIM capacitor on the first dielectric layer. The MIM capacitor is formed from the same material layers used for forming the composite structure.

According, the method of manufacturing the semiconductor device in this present invention, a resistor and a capacitor can be formed on a same chip simultaneously. The processes of forming the two are integrated into the back end of line. The formed resistor can achieve advantages of high resistance or small size, such that the circuit layout is more flexible, and a more competitive electronic product can be manufactured.

In order to the make aforementioned and other objects, features and advantages of the present invention comprehensible, preferred embodiments accompanied with figures are described in detail below.

It is to be understood that both the foregoing general description and the following detailed description are exemplary, and are intended to provide further explanation of the invention as claimed.

### BRIEF DESCRIPTION OF THE DRAWINGS

FIG. 1A is a sectional view of a resistor according an embodiment of the present invention.

FIG. 1B is a sectional view of a semiconductor device according to another an embodiment of the present invention.

FIG. 1C is a sectional view of a semiconductor device according to yet another embodiment of the present invention.

FIGS. 2A to 2C are sectional views illustrating the process steps of fabricating a semiconductor device according to an embodiment of the present invention.

FIG. 2D is a sectional view illustrating the process of fabricating a semiconductor device according to another embodiment of the present invention.

FIG. 2E is a sectional view illustrating the process of fabricating a semiconductor device according to yet another embodiment of the present invention.

### DESCRIPTION OF EMBODIMENTS

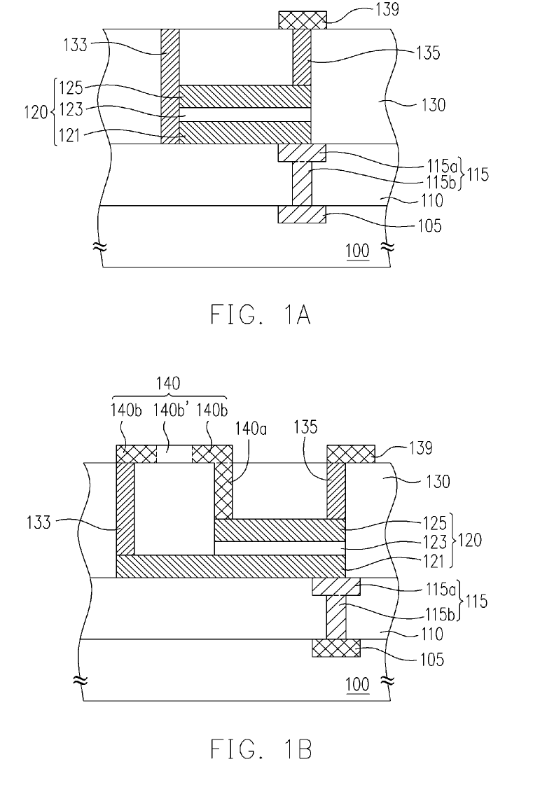

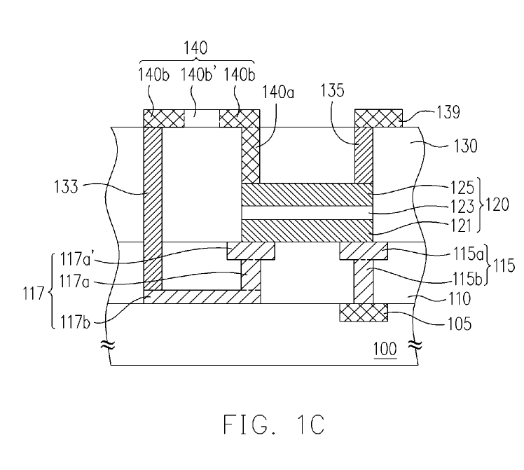

A semiconductor device structure provided by the present invention is illustrated as follows. FIG. 1A is a sectional view of a semiconductor device according to an embodiment of the present invention. Referring to FIG. 1A, the semiconductor device is, for example, disposed on a dielectric layer 110 on a substrate 100, and includes, for example, a composite structure 120 and a contact 133.

The substrate 100 is, for example, a silicon substrate. The substrate 100 is, for example, disposed with a conductive part 105 therein. The material of the dielectric layer 110 is, for example, silicon oxide. The dielectric layer 110 is, for example, disposed with an interconnect structure 115 therein, and is electrically connected with the conductive part 105. The interconnect structure 115 comprises, for example, Al, Cu, W, or an alloy thereof. The width of an upper part 115a of the interconnect structure 115 is, for example, larger than the width of its lower part 115b.

The dielectric layer 110 is, for example, disposed with another dielectric layer 130 formed thereon. The dielectric layer 130 comprises, for example, silicon oxide. The composite structure 120 is, for example, disposed in the dielectric layer 130 on the interconnect structure 115, and is electrically connected with the interconnect structure 115. The composite structure 120 comprises a bottom electrode 121, an insulating layer 123 and an upper electrode 125 from bottom to top. The bottom electrode 121 is, for example, disposed on the dielectric layer 110, and the insulating layer 123 is, for example, disposed between the bottom electrode 121 and the upper electrode 125.

The contact 133 is, for example, disposed on a sidewall of the composite structure 120, and electrically connects the upper electrode 125 and the bottom electrode 121. If the size of the bottom electrode 121 is larger than the size of the upper electrode 125, the contact 133 can be disposed on sidewalls of the upper electrode 125 and the insulating layer 123, and connected to a top surface of the bottom electrode 121, as long as the upper electrode 125 is electrically connected with the bottom electrode 121. Of course, a part of the contact 133 may extend onto the upper electrode 125, and is not limited to the sidewall of the upper electrode 125.

The upper electrode 125 is, for example, disposed with a conductor layer 135 thereon. The conductor layer 135 is electrically connected with the upper electrode 125. The conductor layer 135 can also be disposed with a wire 139 thereon, such that the composite structure 120 can be electrically connected to another element. The conductor layer 135 and the wire 139 is, for example, Al, Cu, W, or an alloy thereof.

If it is desired to elongate the path for the current passing through the upper electrode 125 and the bottom electrode 121, the conductor layer 135 and the interconnect structure 115 can be disposed at the ends of the upper electrode 125 and the bottom electrode 121 not contacting the contact 133.

The material of the upper electrode 125 and the bottom electrode 121 is, for example, selected from a group consisting of Ti, TiN, TiNSi, Ta, TaN, TaC, TaNSi, TaAlN, W, WN, Cr—Ni alloy, CrSi₂, and any mixture thereof. These materials are metal or metal compound with electrical conductivity and high resistance. The common material of electrodes is TiN or TaN.

The material of the insulating layer 123 is, for example, selected from a group consisting of Ta₂O₅, SrTiO₃, ZrO₂, HfO₂, HfSiO, TiO₂, SiO₂, Si₃N₄, and any mixture thereof. The material of the contact 133 is, for example, a conductive material such as Cu, Al, W, or an alloy thereof.

The semiconductor device electrically connects the upper electrode 125 and the bottom electrode 121 through the conductive contact 133 to be used as a resistor. Therefore, the current will flow through the bottom electrode 121 besides the upper electrode 125. As the current transmission path is lengthened, the resistance generated by the semiconductor device (the resistor) is raised.

The top electrode can be electrically connected to bottom electrodes by the contact, or by a combination of the wire structure and the contact. The structure will be further illustrated below. FIG. 1B is a sectional view of a semiconductor device according to another embodiment of the present invention. FIG. 1C is a sectional view of a semiconductor device according to yet another embodiment of the present invention.

Referring to FIG. 1B, the semiconductor device includes a composite structure 120, a contact 133, and a wire structure 140. Besides the wire structure 140, other components of the semiconductor device are the same as those in the above embodiment (FIG. 1A). Therefore, the relative part of the wire structure 140 is described below, and others are the same as those in the above embodiment (FIG. 1A) and will not be described herein.

The composite structure 120 is stacked sequentially by a bottom electrode 121, an insulating layer 123, and an upper electrode 125. The wire structure 140 is disposed on the composite structure 120, and electrically connected with the upper electrode 125, and the contact 133 is electrically connected with the upper electrode 125 by the wire structure 140.

The wire structure 140 can be substantially divided into a wire structure 140a perpendicular to the upper electrode 125 and disposed in the dielectric layer 130, and a wire structure 140b in parallel with the upper electrode 125 and disposed on the dielectric layer 130. If the size of the bottom electrode 121 is larger than the size of the upper electrode 125, the contact 133 can be disposed between the wire structure 140a and the bottom electrode 121. The composite structure 120 is, for example, used as a resistor. The wire structure 140 comprises, for example, Al, Cu, W, or an alloy thereof, and is, for example, the same as that of the contact 133.

Moreover, the wire structure 140 is, for example, selectively disposed with a fuse structure 140a′ therein. The fuse structure 140a′ is, for example, disposed in the wire structure 140a on the dielectric layer 130. When the fuse structure 140a′ passes the current, the composite structure 120 is used as a resistor. When the fuse structure 140a′ is blown and stops passing the current, the composite structure 120 is used as a capacitor.

Referring to FIG. 1C, another wire structure 117 can be disposed in the dielectric layer 110 under the bottom electrode 121, and is electrically connected with bottom electrode 121. And the contact 133 is electrically connected to the bottom electrode 121 by the wire structure 117. The wire structure 117 includes, for example, a wire structure 117a substantially perpendicular to bottom electrode 121 and directly contacting the bottom electrode, and a wire structure 117b approximately in parallel with the bottom electrode and located on the substrate 100.

The contact 133, for example, extends into the dielectric layer 110, and is disposed between the wire structure 117b and the wire structure 140b. The width of a part of the wire structure 117a′ of the wire structure 117a close to the bottom electrode 121 is, for example, larger than the wire structure 117a there-under.

The wire structure 117 comprises, for example, Al, Cu, W, or an alloy thereof, and is, for example, the same as that of the interconnect structure 115. Furthermore, similar to the wire structure 140, the wire structure 170 can be selectively disposed with a fuse structure (not shown) therein, depending on the device design.

The semiconductor device electrically connects the upper electrode 125 and the bottom electrode 121 of the composite structure 120 through the contact 133 and the wire structure, such that the composite structure 120 can be used as a resistor. As the current will pass through the top and bottom electrodes, the current transmission path is doubled, such that the resistance of the resistor is raised. Therefore, even if the size of the resistor is halved, it can still satisfy the requirement for resistance, and is more beneficial for the miniaturization of the device.

Furthermore, the fuse structure 140a′ disposed can be used to control the function of the composite structure 120. If the fuse structure 140a′ is blown and stops passing current, the function of the composite structure 120 is shifted from a resistor to be a capacitor. Therefore, the device design is more changeable, thus increasing the function of the products.

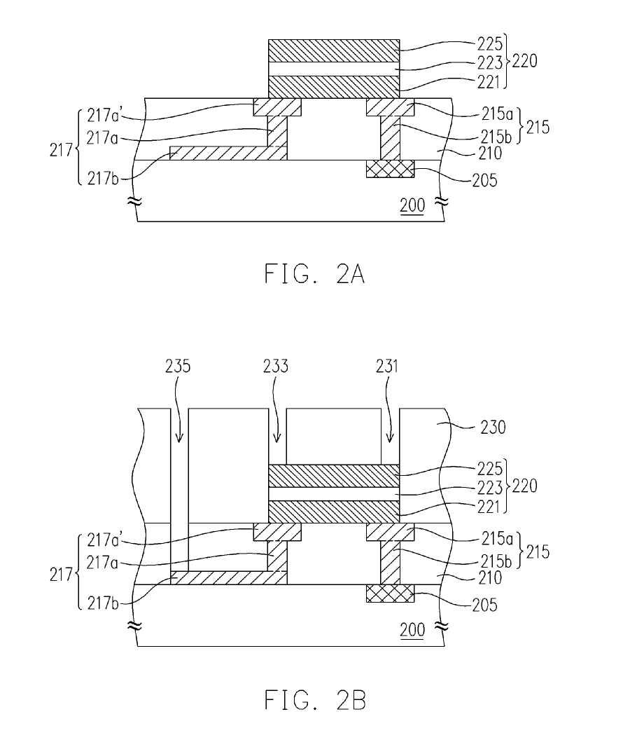

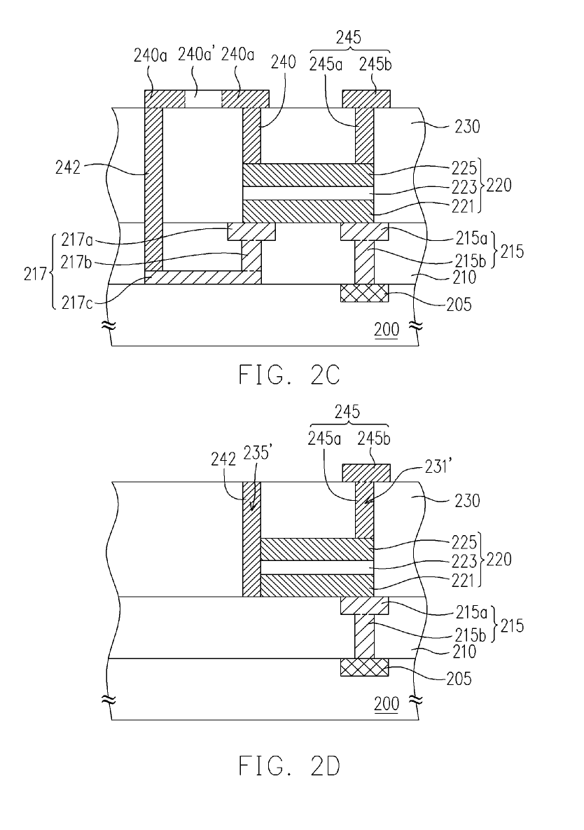

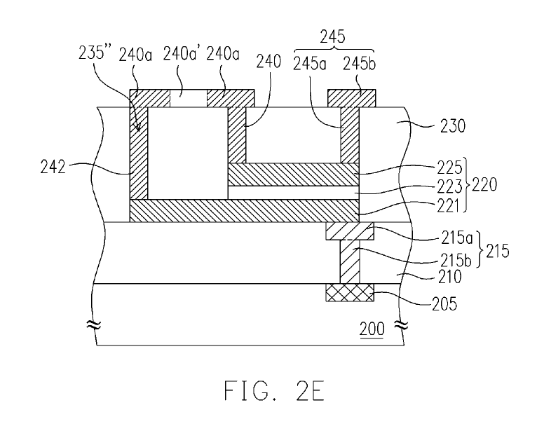

A method for manufacturing the semiconductor device is illustrated below. FIGS. 2A to 2C are sectional views illustrating the process of fabricating a semiconductor device according to an embodiment of the present invention.

Referring to FIG. 2A, in the method, for example, a substrate 200 is provided, wherein the substrate 200 is formed with a conductive part 205 therein. A dielectric layer 210 is formed on the substrate 200. The dielectric layer 210 comprises, for example, silicon oxide, and may be formed by using, for example, chemical vapor deposition process. Next, an interconnect structure 215 is formed in the dielectric layer 210, to electrically connect the conductive part 205. The interconnect structure 215 comprises, for example, a conductive material, such as Cu, Al, or W, and may be formed by methods known to those skilled in the art, and will not be described herein. The width of the upper part 215a of the interconnect structure 215 is, for example, larger than the width of the lower part 215b.

When forming the interconnect structure 215, for example, a wire structure 217 is formed in the dielectric layer 210 at the same time. The material of the wire structure 217 is, for example, the same as the material of the interconnect structure 215, and may be formed using the process, for example, the same as that used in fabricating an ordinary interconnect structure, and will not be described herein. Of course, the part 217c of the wire structure 217 in parallel with the horizontal plane can be formed before the interconnect structure 215 is formed, but cannot be formed together with other parts of the wire structure 217. The width of the upper part 217a of the wire structure 217 perpendicular to the horizontal plane is, for example, larger than the width of the lower part 217b. Furthermore, the wire structure 217c can also be selectively disposed with a fuse structure (not shown) therein.

Referring to FIG. 2A, a composite structure 220 is formed on the dielectric layer 210. The composite structure 220 is formed by sequentially stacking a bottom electrode 221, an insulating layer 223 and an upper electrode 225. The bottom electrode 221 electrically connects the interconnect structure 215 and the wire structure 217. The method for forming the composite structure 220 comprises, for example, forming a bottom electrode material layer (not shown), an insulating material layer (not shown), and an upper electrode material layer (not shown) respectively, and then patterning the upper electrode material layer, the insulating material layer and the bottom electrode material layer.

The material of the bottom electrode 221 and the upper electrode 225 is, for example, selected from a group consisting of Ti, TiN, TiNSi, Ta, TaN, TaC, TaNSi, TaAlN, W, WN, Cr—Ni alloy, CrSi₂, and any mixture thereof. The material of the insulating layer 223 is, for example, selected from a group consisting of Ta₂O₅, SrTiO₃, ZrO₂, HfO₂, HfSiO, TiO₂, SiO₂, Si₃N₄, and any mixture thereof. The method for forming the material layers includes, for example, chemical vapor deposition. The method for patterning the material layers includes, for example, dry etching, such as reactive ion etching.

It should be noted that, as the material of each layer of the composite structure 220 comprises metal (compound), an insulating layer, and metal (compound) respectively, the three layers of material can be used as a MIM capacitor. Therefore, when the composite structure 220 is formed, the material layers can be used to form a MIM capacitor (not shown) in other regions on the dielectric layer 210 in the patterning step.

Referring to FIG. 2B, a dielectric layer 230 is formed on the dielectric layer 210, covering the composite structure 220. The dielectric layer 230 comprises, for example, a dielectric material such as silicon oxide, and may be formed using, for example, chemical vapor deposition process.

Next, an opening 231 and an opening 233 are formed in the dielectric layer 230, and an opening 235 is formed in the dielectric layer 230 and the dielectric layer 210. The opening 231 and the opening 233 expose a part of the upper electrode 225, and the opening 235, for example, exposes the wire structure 217c. The method for forming the opening 231 and the openings 233, 235 includes, for example, a photolithographic and etching process.

Of course, the opening 231 can also be a dual damascene opening, other than a single damascene opening as shown in FIG. 2B, depending on the process design. The opening 233 and the opening 235 can also be dual damascene openings, and the opening 233 communicates with the upper part of the upper electrode 225 in parallel with the opening 235.

Referring to FIG. 2C, a conductive material layer (not shown) is formed on the dielectric layer 230 filling the openings 231, 233, and 235, and covers the dielectric layer 230. The conductive material layer includes, for example, a conductive material such as Al, Cu, W, or an alloy thereof, and may be formed using, for example, physical vapor deposition or chemical vapor deposition process. The conductive material layer on the dielectric layer 230 is patterned to form a wire structure 240 and a contact 242 on the left side of the composite structure 220, and a conductor layer 245 on the right side of the composite structure 220. The method for patterning the conductive material layer includes, for example, dry etching.

The wire structure 240 is electrically connected with the upper electrode 225. The contact 242 electrically connects the wire structure 240a (a part of the wire structure 240 in parallel with the upper electrode 225) and the wire structure 217c. The conductor layer 245, for example, includes a plug 245a and a wire 245b, in which the plug 245a electrically connects the upper electrode 225 and the wire 245b.

A fuse structure 240a′ can be formed in the conductor layer 240a. If the fuse structure 240a′ can allow the current to pass through, the composite structure 220 is used as a resistor. If the fuse structure 240a′ is blown and stops passing current, the composite structure 220 is used as a capacitor. The fuse structure 240a′ comprises, for example, Cu, Al, W, or an alloy thereof. If the wire structure 217 is formed with a fuse structure therein, the material and function thereof are the same as those of the fuse structure 240a′.

It can be known from aforementioned illustration of the semiconductor device structure that, the method for manufacturing the semiconductor device provided by the present invention is not limited to the method of FIGS. 2A to 2C.

Referring to FIG. 2B and FIG. 2D, the dielectric layer 210 can be only formed with the interconnect structure 215, without the wire structure 217. Furthermore, in the step of forming the opening, only the opening 231′ that exposes the top surface of the upper electrode225 and the opening 235′ that at least exposes sidewalls of the upper electrode 225 and the bottom electrode 221 are required to form in the dielectric layer 220. The contact 242 formed subsequently is located on the sidewall of the composite structure 220. If the opening 235″ exposes the top surface of the upper electrode 225, the contact 242 will be disposed on the top surface of the upper electrode 225.

Alternatively, referring to FIG. 2B and FIG. 2E, if the size of the bottom electrode 221 is larger than that of the upper electrode 225, it is unnecessary to form the wire structure 217 in the dielectric layer 210. And when forming the opening 235″, the bottom electrode 221 is used as an etching stop layer, such that the opening will not go too deep into the dielectric layer 210. Therefore, the contact 242 is formed on the bottom electrode 221 instead, and is electrically connected with the upper electrode 225 via the wire structure 240.

It should be noted that various structures and manufacturing methods of the interconnect structure and the wire structure are shown in many periodicals and patents, and are known to those skilled in the art. Therefore, the structure and manufacturing method thereof are not limited to the one described in aforementioned embodiments or drawings.

In aforementioned method for manufacturing the semiconductor device, a resistor and a capacitor can be formed simultaneously on the same chip, and the two processes are integrated in the back end of line. The resistor formed can gain advantages of higher resistance and smaller size, such that the circuit layout can be more flexible, and a more competitive electronic product can be manufactured.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A semiconductor device, comprising:
a composite structure, having a bottom electrode, an insulating layer and an upper electrode; and
a contact, electrically connecting the upper electrode and the bottom electrode.

2. The semiconductor device as claimed in claim 1, wherein the contact is disposed on a sidewall of the composite structure.

3. The semiconductor device as claimed in claim 1, further comprising a first wire structure disposed on the composite structure and electrically connected with the upper electrode, wherein the contact is electrically connected with the upper electrode by the first wire structure.

4. The semiconductor device as claimed in claim 3, wherein the size of the bottom electrode is larger than the size of the upper electrode, and the contact is disposed between the first wire structure and the bottom electrode.

5. The semiconductor device as claimed in claim 4, further comprising a first fuse structure disposed in the first wire structure.

6. The semiconductor device as claimed in claim 3, further comprising a second wire structure, wherein the second wire structure is disposed under the bottom electrode and electrically connected with the bottom electrode, and the contact is electrically connected with the bottom electrode by the second wire structure.

7. The semiconductor device as claimed in claim 6, further comprising a first fuse structure disposed in the first wire structure.

8. The semiconductor device as claimed in claim 7, wherein when the first fuse structure passes a current, the composite structure is used as a resistor.

9. The semiconductor device as claimed in claim 7, wherein when the first fuse structure stops passing the current, the composite structure is used as a capacitor.

10. The semiconductor device as claimed in claim 6, further comprising a second fuse structure disposed in the second wire structure.

11. The semiconductor device as claimed in claim 1, wherein a material of the upper electrode and the bottom electrode is selected from a group consisting of Ti, TiN, TiNSi, Ta, TaN, TaC, TaNSi, TaAlN, W, WN, Cr—Ni alloy, CrSi₂, and mixture thereof.

12. The semiconductor device as claimed in claim 1, wherein a material of the insulating layer is selected from a group consisting of Ta₂O₅, SrTiO₃, ZrO₂, HfO₂, HfSiO, TiO₂, SiO₂, Si₃N₄, and mixture thereof.

13. The semiconductor device as claimed in claim 1, wherein the contact comprises Cu, Al, W, or an alloy thereof.

14. A method for manufacturing the semiconductor device, comprising:
providing a substrate comprising at least a conductive part formed therein;
forming a first dielectric layer on the substrate;
forming an interconnect structure in the first dielectric layer to electrically connect the conductive part;
forming a composite structure on the first dielectric layer, wherein the composite structure is formed by stacking a bottom electrode, an insulating layer and an upper electrode, in which the bottom electrode is electrically connected with the interconnect structure;
forming a second dielectric layer on the first dielectric layer to cover the composite structure; and
forming a conductor layer and a contact in the second dielectric layer, wherein the conductor layer is electrically connected with the upper electrode, and the contact is electrically connected to the upper electrode and the bottom electrode.

15. The method for manufacturing the semiconductor device as claimed in claim 14, wherein the contact is formed on a sidewall of the composite structure.

16. The method for manufacturing the semiconductor device as claimed in claim 14, wherein the step of forming the conductor layer and the contact in the second dielectric layer comprises:
forming an opening and a contact opening in the second dielectric layer, wherein the opening exposes a part of the upper electrode, and the contact opening at least exposes sidewalls of the upper electrode and the bottom electrode; and
filling a conductive material in the opening and the contact opening to form the conductor layer and the contact.

17. The method for manufacturing the semiconductor device as claimed in claim 14, in the step of forming the conductor layer and the contact, further comprising a step of forming a first wire structure in the second dielectric layer, wherein the first wire structure is electrically connected with the upper electrode, and the contact is electrically connected with the upper electrode by the first wire structure.

18. The method for manufacturing the semiconductor device as claimed in claim 17, wherein the size of the bottom electrode is larger than the size of the upper electrode, and the contact is formed between the first wire structure and the bottom electrode.

19. The method for manufacturing the semiconductor device as claimed in claim 17, further comprising forming a fuse structure in the first wire structure.

20. The method for manufacturing the semiconductor device as claimed in claim 17, in the step of forming the interconnect structure, further comprising a step of forming a second wire structure in the first dielectric layer, wherein the bottom electrode is electrically connected with the second wire structure, and the contact extends into the first dielectric layer to be connected with the second wire structure, and is electrically connected with the bottom electrode via the second wire structure.

21. The method for manufacturing the semiconductor device as claimed in claim 14, wherein the conductor layer comprises an interconnect.

22. The method for manufacturing the semiconductor device as claimed in claim 14, wherein a material of the upper electrode and the bottom electrode is selected from a group consisting of Ti, TiN, TiNSi, Ta, TaN, TaC, TaNSi, TaAlN, W, WN, Cr—Ni alloy, CrSi₂, and mixture thereof.

23. The method for manufacturing the semiconductor device as claimed in claim 14, wherein a material of the insulating layer is selected from a group consisting of Ta₂O₅, SrTiO₃, ZrO₂, HfO₂, HfSiO, TiO₂, SiO₂, Si₃N₄, and mixture thereof.

24. The method for manufacturing the semiconductor device as claimed in claim 14, wherein the contact comprises Cu, Al, W, or an alloy thereof.

25. The method for manufacturing the semiconductor device as claimed in claim 14, in the step of forming the composite structure, further comprising a step of forming a MIM capacitor on the first dielectric layer, wherein the MIM capacitor is formed from the same material layers used for forming the composite structure.
